(19) United States
(12) Patent Application Publication
(10) Pub. No.: US 2011/0076400 A1
(43) Pub. Date: Mar. 31, 2011

(54) NANOCRYSTALLINE DIAMOND-STRUCTURED CARBON COATING OF SILICON CARBIDE

(75) Inventors: Olga Kryliouk, Sunnyvale, CA (US); Yuriy Melnik, Santa Clara, CA (US); Brian H. Burrows, San Jose, CA (US); Ronald Stevens, San Ramon, CA (US); Jacob Grayson, Midland, MI (US); Sandeep Nijhawan, Los Altos, CA (US)

(73) Assignee: Applied Materials, Inc., Santa Clara, CA (US)

(21) Appl. No.: 12/888,302

(22) Filed: Sep. 22, 2010

Related U.S. Application Data
(60) Provisional application No. 61/247,495, filed on Sep. 30, 2009.

(51) Int. Cl. C23C 16/27; C23C 16/26; C23C 16/44

(52) U.S. Cl. 427/249.8; 427/249.1

(57) ABSTRACT

One embodiment of the forming a nanocrystalline diamond-structured carbon layer on a silicon carbide layer comprises providing a silicon carbide layer in a reaction chamber and exposing the silicon carbide layer to a chlorine containing gas for an exposure time period to form a nanocrystalline diamond-structured carbon layer from the silicon carbide layer.

This application claims the benefit of and priority to Provisional Application Ser. No. 61/247,495, filed Sep. 30, 2009 which is hereby incorporated by reference.

### BACKGROUND

1. Field

Embodiments of the present invention relate to forming a nanocrystalline diamond-structured carbon layer on a silicon carbide layer.

2. Discussion of Related Art

Chemical vapor deposition (CVD) reactor parts made of silicon carbide can deteriorate over time when exposed to chlorinated environments at high temperature. One example of this is during an insitu clean of a CVD reactor, which typically uses HCl or Cl₂ at elevated temperatures to clean the CVD reactor. Deterioration of CVD reactor parts can occur in a variety of processing chambers including CVD reactor chambers, metal organic chemical vapor deposition (MOCVD) reactor chambers, and hydride vapor phase epitaxy (HVPE) reactor chambers. Hence, a chemically inert and mechanically stable protective layer on silicon carbide is desirable to prevent deterioration of silicon carbide CVD reactor parts.

### BRIEF DESCRIPTION OF THE DRAWINGS

FIG. 1 is an illustration of a carbon-silicon carbide structure in accordance with an embodiment of the present invention.

FIG. 2 is an illustration of process steps for forming a carbon layer on a silicon carbide layer in accordance with an embodiment of the present invention.

FIG. 3 is a FIB XSEM/EDX showing a carbon-silicon carbide structure formed in accordance with an embodiment of the present invention.

FIG. 4A is a chart of minimum/maximum thickness of a carbide derived carbon (CDC) film formed in accordance with an embodiment of the present invention

FIG. 4B is a high resolution Auger Electron Spectroscopy (AES) study of a carbon layer formed in accordance with an embodiment of the present invention.

FIG. 5 is an isometric view illustrating a processing system according to an embodiment of the invention.

FIG. 6 is a plan view of the processing system illustrated in FIG. 7.

FIG. 7 is an isometric view illustrating a load station and loadlock chamber according to an embodiment of the invention.

FIG. 8 is a schematic view of a loadlock chamber according to an embodiment of the invention.

FIG. 9 is an isometric view of a carrier plate according to an embodiment of the invention.

FIG. 10 is a schematic view of a batch loadlock chamber according to an embodiment of the invention.

FIG. 11 is an isometric view of a work platform according to an embodiment of the invention.

FIG. 12 is a plan view of a transfer chamber according to an embodiment of the invention.

FIG. 13 is a schematic cross-sectional view of a HVPE chamber according to an embodiment of the invention.

FIG. 14 is a schematic cross-sectional view of an MOCVD chamber according to an embodiment of the invention.

FIG. 15 is a schematic view illustrating another embodiment of a processing system for fabricating compound nitride semiconductor devices.

FIG. 16 is a schematic view illustrating yet another embodiment of a processing system for fabricating compound nitride semiconductor devices.

### SUMMARY

A method of forming a nanocrystalline diamond structure-carbon layer is described. According to embodiments of the present invention, a silicon carbide layer is exposed to a chlorine containing gas for an exposure time period sufficient to allow the formation of a nanocrystalline diamond-structure carbon layer. In an embodiment of the present invention, a silicon carbide layer is exposed to a chlorine containing gas, such as but not limited to Cl₂ or HCl while the silicon carbide layer is heated to a temperature greater than 600° C. and generally between 600-1000° C.

### DETAILED DESCRIPTION

Embodiments of the present invention relate to a method of forming a nanocrystalline diamond-structured carbon layer. In the present description, numerous specific details have been set forth in order to provide a thorough understanding of the present invention. In other instances, well known semiconductor processes and equipment have not been described in specific detail in order to not unnecessarily obscure the present invention.

Embodiments of the present invention describe a method of forming a nanocrystalline diamond-structured carbon layer on a silicon carbide layer. In an embodiment of the present invention, a silicon carbide layer is provided in a reaction chamber and exposed to a chlorine containing gas for an exposure time period at a temperature sufficiently high to allow for the formation of a nanocrystalline diamond-structured carbon layer on the silicon carbide (SiC) layer. In an embodiment of the present invention, the limited reaction kinetics of the chlorine (Cl) and silicon carbide (SiC) reaction allows for the controlled formation of the nanocrystalline diamond-structured carbon layer on the silicon carbide (SiC) layer. The nanocrystalline diamond-structured carbon layer can be formed to a desired thickness by controlling the exposure time period and temperature of the silicon carbide layer to the chlorine containing gas in accordance with an embodiment of the present invention.

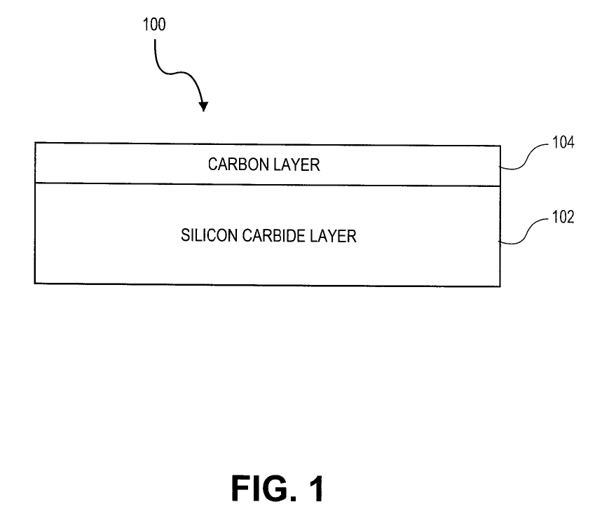

FIG. 1 illustrates a carbon-silicon carbide structure 100 in accordance with an embodiment of the present invention. In an embodiment of the present invention, the carbon-silicon carbide structure 100 may comprise a silicon carbide layer 102 with a carbon layer 104 formed on silicon carbide layer 102. In a specific embodiment of the present invention, the silicon carbide layer 102 is a single crystalline silicon carbide layer. In other embodiments the silicon carbide layer may be a pressed silicon carbide layer or a polycrystalline silicon carbide layer. In embodiments of the present invention, the silicon carbide layer 102 can be a silicon carbide substrate or wafer, a silicon carbide layer on a different type of substrate or wafer, or can be a CVD reactor part. In an embodiment of the present invention, a surface portion of silicon carbide layer 102 is transformed into carbon layer 104 thereby forming a carbide derived carbon (CDC) layer 104. In a specific embodiment of the present invention, the carbon layer 104 is a nanocrystalline diamond-structured carbon layer or a “diamond like” carbon layer 104.

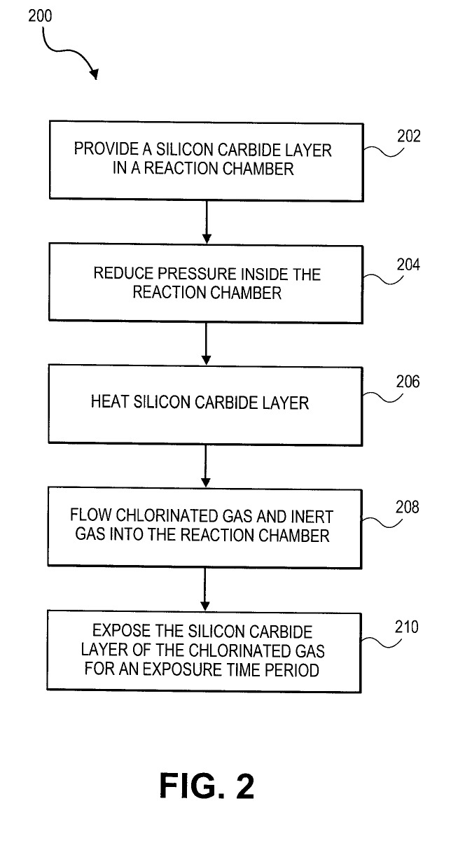

FIG. 2 illustrates process steps 200 of forming carbon layer 104 on silicon carbide layer 102 in accordance with an embodiment of the present invention. Embodiments of process steps 200 may comprise providing silicon carbide layer 102 in a reaction chamber, as set forth in block 202; reducing the pressure inside the reaction chamber, as set forth in block 204; heating the silicon carbide layer 102, as set forth in block 206; flowing a chlorine containing gas and an inert gas into the reaction chamber, as set forth in block 208; and exposing the silicon carbide layer 102 to a chlorine containing gas for an exposure time period, as set forth in block 210.

In an embodiment of the present invention, block 204 may comprise reducing the reaction chamber pressure to a pressure sufficiently low to facilitate the formation of carbon layer 104 on silicon carbide layer 102. In a specific embodiment of the present invention, the reaction chamber pressure can be between 5 torr and 760 torr. In an embodiment of the present invention, block 206 may comprise heating the silicon carbide layer 102 to a temperature sufficiently high to allow the formation of carbon layer 104 on the silicon carbide layer 102. In an embodiment of the present invention silicon carbide layer 102 is heated to a temperature greater than 600° C. In a specific embodiment of the present invention the silicon carbide layer 104 is heated to a temperature between 600° C. and 1000° C. In an embodiment of the present invention, the temperature of the silicon carbide layer 102 is constant throughout process steps 200.

In an embodiment of the present invention, as set forth in block 208 the silicon carbide layer 102 is exposed to a chlorinated ambient by flowing a chlorine containing gas and an inert gas into the reaction chamber. The chlorine containing gas can be any suitable chlorine containing gas, such as but not limited to gaseous HCl or Cl₂. The inert gas can be any suitable inert gas, such as but not limited to N₂, Ar or He. In embodiments of the present invention, the chlorine containing gas and the inert gas can be introduced into the reaction chamber at a flow rate between 1.0 and 7.0 standard liter per minute (SLM). In a specific embodiment of the present invention, the silicon carbide layer is exposed to Cl₂ at a flow rate of 1 SLM and N₂ at a flow rate of 6 SLM.

In one embodiment, the chlorine containing gas reacts with an exposed surface portion of silicon carbide layer 102. However, the chlorine containing gas reacts more favorably with the silicon atoms than the carbon atoms of the silicon carbide layer 102. As a result, chlorine atoms from the chlorine containing gas form silicon-chlorine bonds with silicon atoms of the silicon carbide layer 102 to form gaseous silicon tetrachloride (SiCl₄). Meanwhile, carbon atoms of the silicon carbide layer 102 remain unreacted. In an example using gaseous Cl₂, one molar equivalent of silicon carbide layer 102 (SiC) reacts with two molar equivalents of gaseous chlorine (Cl₂) to provide one molar equivalent of gaseous silicon tetrachloride (SiCl₄), while one molar equivalent of carbon (C) remains unreacted. The balanced reaction equation is:

SiC+2Cl₂(g)=SiCl₄(g)+C

The gaseous silicon tetrachloride (SiCl₄) is removed from the reaction chamber while the carbon remains to provide carbon layer 104 on the silicon carbide layer 102, in accordance with an embodiment of the present invention. Thus, the exposed surface portion of silicon carbide layer 102 is transformed into carbon layer 104. In one embodiment, carbon layer 104 is a diamond layer and has a three-dimensional network of ordered carbon atoms, as opposed to a two-dimensional network of carbon atoms as is found in graphite. In a specific embodiment, carbon layer 104 is a nano-structured diamond layer.

The chlorine containing gas may react more favorably with the silicon atoms than the carbon atoms of silicon carbide layer 102 for kinetic reasons. For example, the formation of gaseous silicon tetrachloride (SiCl₄) is much more favorable than the formation of gaseous carbon tetrachloride (CCl₄). In other words, chlorine reacts faster with silicon than carbon because less energy is required to activate the reaction. Furthermore, the kinetic energetics of silicon-chlorine bond formation is more rapid than for carbon-chlorine bond formation. In one embodiment, kinetic factors allow the chlorine containing gas to selectively react with the silicon atoms, instead of the carbon atoms, present at the surface of silicon carbide layer 102.

In an embodiment of the present invention, block 210 may comprise exposing the silicon carbide layer 102 to the chlorine containing gas for an exposure time period. The reaction between the chlorine containing gas and the silicon carbide layer 102 is a kinetically limited reaction. The limited reaction kinetics of the chlorine and silicon carbide reaction allows for controlled transformation of the silicon carbide into a carbon layer 104 of a desired thickness in accordance with an embodiment of the present invention. In an embodiment of the present invention, carbon layer 104 can be formed, in the manner described above, to a desired thickness by controlling the exposure time period of the silicon carbide layer 102 to the chlorine containing gas. In an embodiment of the present invention, the silicon carbide layer 102 is exposed to a chlorinated ambient for between one minute to 12 hours to form a carbon layer having a thickness between 3-15 μm. In an embodiment of the present invention, the transformation of silicon carbide to carbon begins to saturates after an exposure period of about 3.0 hours.

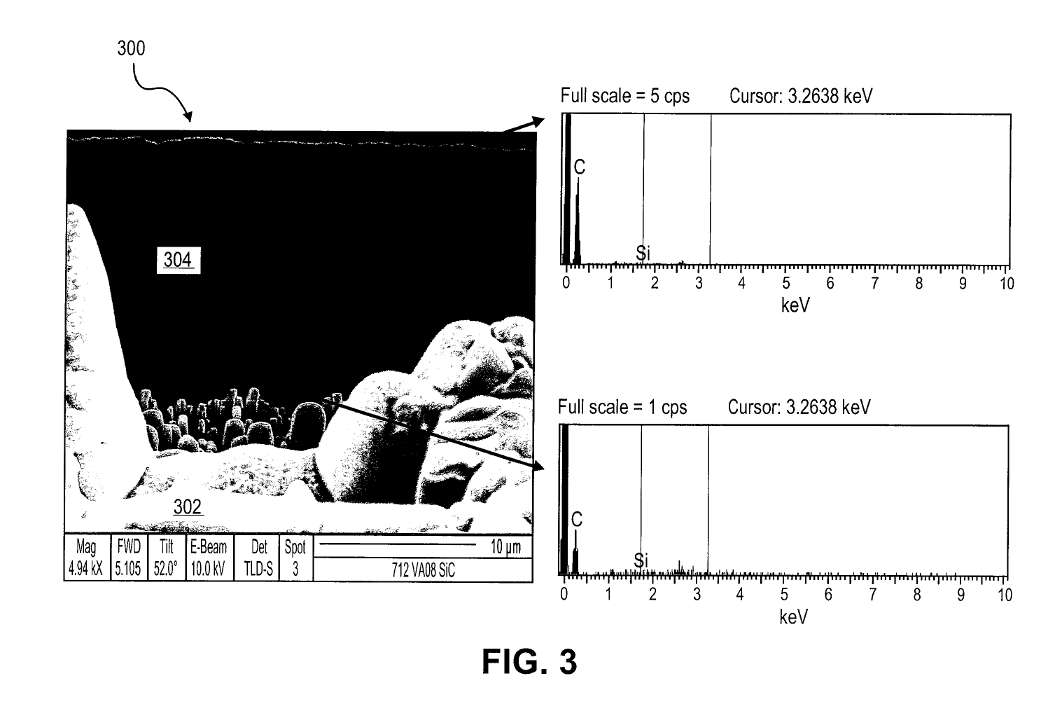

FIG. 3 illustrates a FIB XSEM/EDX showing a carbon-silicon carbide structure 300 formed in accordance with an embodiment of the present invention. Carbon-silicon carbide structure 300 includes a silicon carbide layer 302 and a carbon layer 304. In a specific embodiment of the present invention, a carbide derived carbon (CDC) layer 304 was produced by C12 treatment of a Bridgestone Silicon Carbide (SiC) film 302 (Bridgestone SiC films are currently used as susceptors and carrier materials in Applied Materials reactors, such as chemical vapor deposition (CVD) reactors). Specifically the carbide derived carbon (CDD) layer 304 was formed by reducing the chamber pressure to 450 torr, heating the silicon carbide layer 302 to a temperature of 950° C., introducing Cl₂ into the reaction chamber at a flow rate of 1 SLM, introducing N₂ into the chamber at a flow rate of 7 SLM, and exposing the silicon carbide layer 302 to the chlorine containing gas for an exposure time period of 12 hours. Carbon layer 304, formed on silicon carbide layer 302, is nanocrystalline diamond-structured carbon layer in accordance with an embodiment of the present invention.

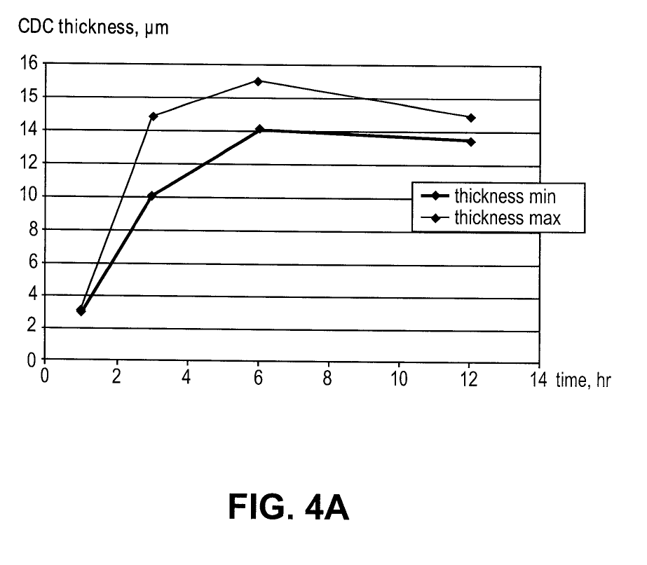

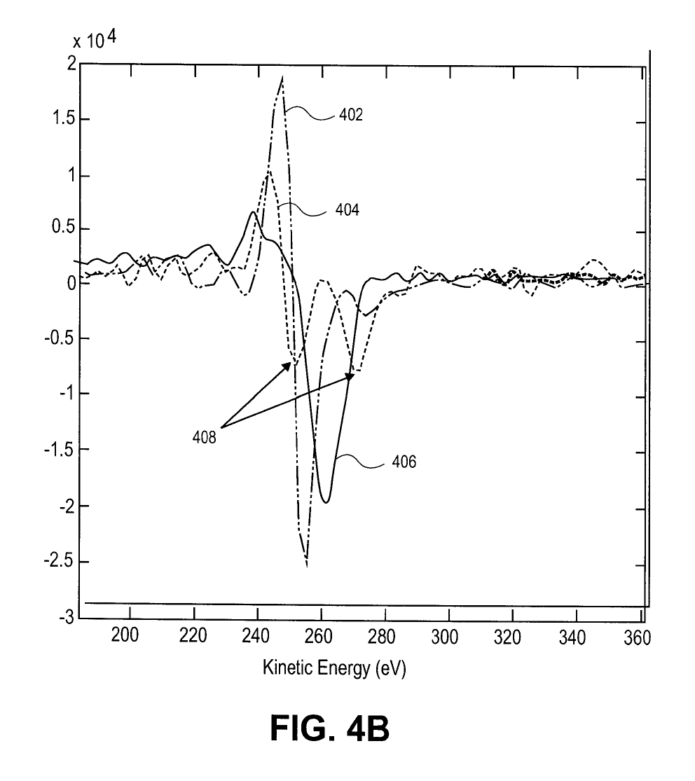

FIG. 4A is an illustration of the minimum and maximum thickness plots of the resulting carbon layer 304 when silicon carbide layer 302 is exposed to chlorine ambient under the condition set forth above for 1, 3, 6 and 12 hours. In embodiment of the present invention, carbon layer 304 can be formed to a thickness of between 3.0 microns and 15.0 microns with an exposure time period between 1.0 hours and 12.0 hours. In a specific embodiment of the present an exposure time period of 1.0 hours formed a carbon layer with a minimum thickness of about 3.0 microns and a maximum thickness of about 3.0 microns. In other embodiments of the present invention, an exposure time period of 3.0 hours formed a carbon layer with a minimum thickness of 10.0 microns and a maximum thickness of 15.0 microns, an exposure time period of 6.0 hours formed a carbon layer with a minimum thickness of 14.0 microns and a maximum thickness of 17.0 microns, and an exposure time period of 12.0 hours formed a carbon layer with a minimum thickness of 13.5 microns and a maximum thickness of 15.0 microns.

FIG. 4B illustrates a high resolution Auger Electro Spectroscopy (AES) study 400 of the carbon layer 304. Diamond-like carbon reference line 402 depicts the AES spectra of a carbon layer having a diamond-like structure. Graphitic carbon reference line 404 depicts the AES spectra of a carbon layer having a graphitic structure. Carbon layer spectra line 406 depicts the AES spectra of carbon layer 304 formed in the manner described above with an exposure time of one hour. Diamond-like carbon reference line 402 and graphitic carbon reference line 404 are overlaid on carbon layer spectra line 406 to illustrate the type of carbon structure carbon layer 304 comprises. Graphitic carbon reference line 404 has a notable double peak 408 at higher kinetic energy, in the AES study, that is characteristic of graphitic structures. Absence of the double peak 408 in the carbon layer spectra line 406 and the similarity of the carbon layer spectra line 406 to the diamond-like reference line 402 indicate that carbon layer 304 is a nanocrystalline diamond-structured carbon layer that was formed in accordance with an embodiment of the present invention.

Thus, the process method 200 described above transforms the exposed surface of a silicon carbide layer into a nanocrystalline diamond-structured carbon layer in accordance with an embodiment of the present invention. A nanocrystalline diamond-structured carbon layer is mechanically stable and chemically inert. Such characteristics make a nanocrystalline diamond-structured carbon layer useful in a wide variety of industrial and commercial applications due to the high corrosion resistance of such a layer. Specifically, these characteristics are desirable for CVD or HVPE reactor parts which are exposed to chlorinated environments at high temperature. Silicon carbide coated with a nanocrystalline diamond-structured layer can be used in any application where corrosion resistance is desirable. Additionally, in embodiments of the present application, the nanocrystalline diamond-structured layer may be harvested from the silicon carbide layer and used in a wide variety of industrial and commercial applications in addition to those mentioned above.

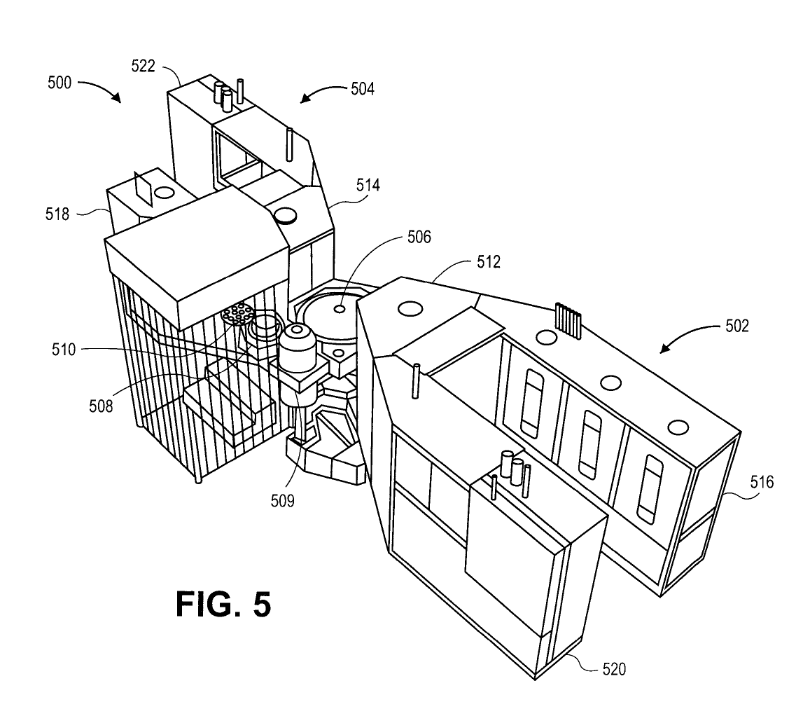

The process of forming a nanocrystalline diamond structure carbon layer can be carried out in any chamber which as chlorine (Cl₂) gas, such as but not limited to, a chemical vapor deposition chamber (CVD), a metal organic chemical vapor deposition chamber (MOCVD) and a hydride vapor phase epitaxial (HVPE) chamber. In an embodiment of the present invention, the nanocrystalline diamond structure carbon layer can be formed in a process system 500, such as illustrated in FIG. 5, which contains an HVPE chamber and a MOCVD chamber, typically used to form light emitting diodes.

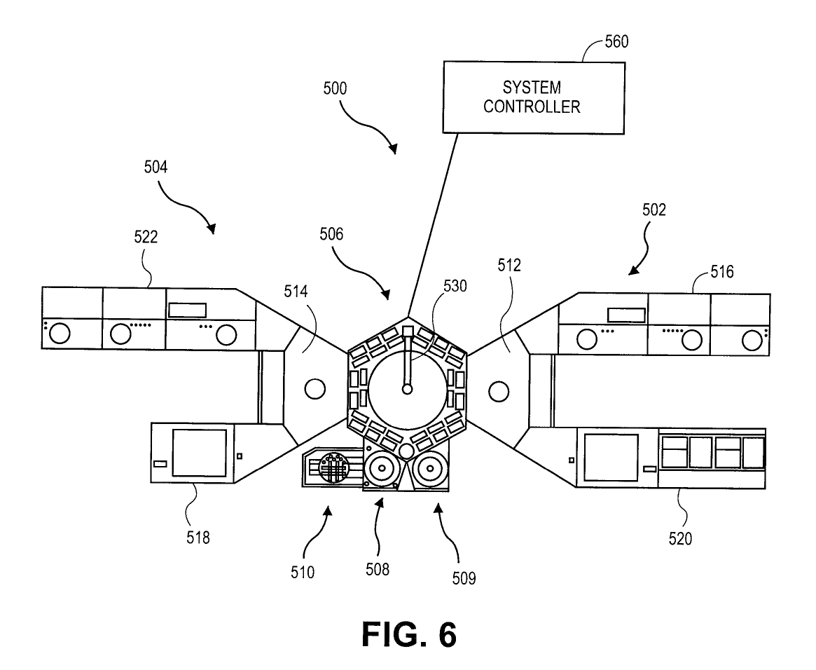

FIG. 5 is an isometric view of one embodiment of a processing system 500 that illustrates a number of aspects of the present invention that may be advantageously used. FIG. 6 illustrates a plan view of one embodiment of a processing system 500 illustrated in FIG. 5. With reference to FIG. 5 and FIG. 6, the processing system 500 comprises a transfer chamber 506 housing a substrate handler, a plurality of processing chambers coupled with the transfer chamber, such as a MOCVD chamber 502 and a HVPE chamber 504, a loadlock chamber 508 coupled with the transfer chamber 506, a batch loadlock chamber 509, for storing substrates, coupled with the transfer chamber 506, and a load station 510, for loading substrates, coupled with the loadlock chamber 508. The transfer chamber 506 comprises a robot assembly 530 operable to pick up and transfer substrates between the loadlock chamber 508, the batch loadlock chamber 509, the MOCVD chamber 502 and the HVPE chamber 504. The movement of the robot assembly 530 may be controlled by a motor drive system (not shown), which may include a servo or stepper motor.

Each processing chamber comprises a chamber body (such as element 512 for the MOCVD chamber 502 and element 514 for the HVPE chamber 504) forming a processing region where a substrate is placed to undergo processing, a chemical delivery module (such as element 516 for the MOCVD chamber 502 and element 518 for the HVPE chamber 504) from which gas precursors are delivered to the chamber body, and an electrical module (such as element 520 for the MOCVD chamber 502 and element 522 for the HVPE chamber 504) that includes the electrical system for each processing chamber of the processing system 500. The MOCVD chamber 502 is adapted to perform CVD processes in which metalorganic elements react with metal hydride elements to form thin layers of compound nitride semiconductor materials. The HVPE chamber 504 is adapted to perform HVPE processes in which gaseous metal halides are used to epitaxially grow thick layers of compound nitride semiconductor materials on heated substrates. The nanocrystalline diamond structure carbon coating of the present invention may be formed on silicon carbide containing substrates placed in MOCVD chamber 502 and/or HVPE chamber 504 or may be formed on silicon carbide components or parts, such as substrate carriers, of MOCVD chamber 502 and/or HVPE chamber 504. In alternate embodiments, one or more additional chambers may 570 be coupled with the transfer chamber 506. These additional chambers may include, for example, anneal chambers, clean chambers for cleaning carrier plates, or substrate removal chambers. The structure of the processing system permits substrate transfers to occur in a defined ambient environment, including under vacuum, in the presence of a selected gas, under defined temperature conditions, and the like.

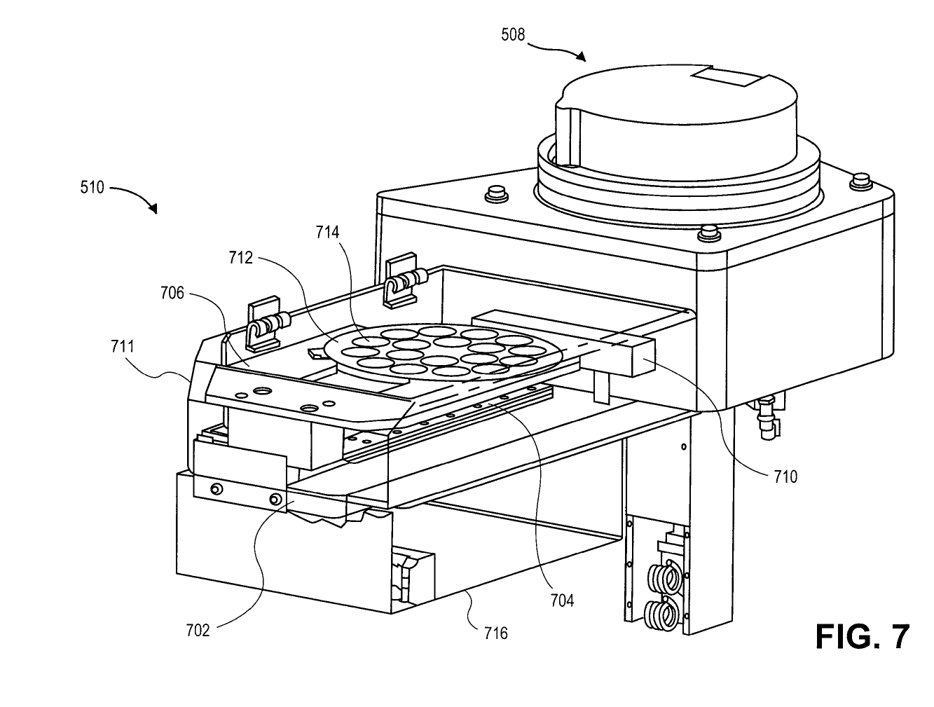

FIG. 7 is an isometric view illustrating a load station 510 and a loadlock chamber 508 according to an embodiment of the invention. The load station 510 is configured as an atmospheric interface to allow an operator to load a plurality of substrates for processing into the confined environment of the loadlock chamber 508, and unload a plurality of processed substrates from the loadlock chamber 508. The load station 510 comprises a frame 702, a rail track 704, a conveyor tray 706 adapted to slide along the rail track 704 to convey substrates into and out of the loadlock chamber 508 via a slit valve 710, and a lid 711. In one embodiment, the conveyor tray 706 may be moved along the rail track 704 manually by the operator. In another embodiment, the conveyor tray 706 may be driven mechanically by a motor. In yet another embodiment, the conveyor tray 706 is moved along the rail track 704 by a pneumatic actuator.

Substrates for processing may be grouped in batches and transported on the conveyor tray 706. For example, each batch of substrates 714 may be transported on a carrier plate 712 that can be placed on the conveyor tray 706. The lid 711 may be selectively opened and closed over the conveyor tray 706 for safety protection when the conveyor tray 706 is driven in movement. In operation, an operator opens the lid 711 to load the carrier plate 712 containing a batch of substrates on the conveyor tray 706. A storage shelf 716 may be provided for storing carrier plates containing substrates to be loaded. The lid 711 is closed, and the conveyor tray 706 is moved through the slit valve 710 into the loadlock chamber 508. The lid 711 may comprise a glass material, such as Plexiglas or a plastic material to facilitate monitoring of operations of the conveyor tray 706.

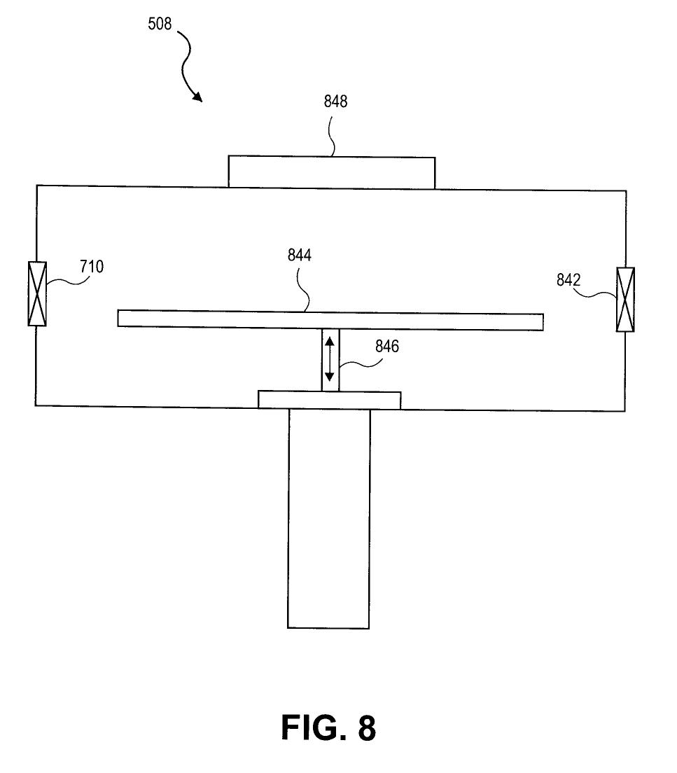

FIG. 8 is a schematic view of a loadlock chamber 508 according to an embodiment of the invention. The loadlock chamber 508 provides an interface between the atmospheric environment of the load station 510 and the controlled environment of the transfer chamber 506. Substrates are transferred between the loadlock chamber 508 and the load station 510 via the slit valve 710 and between the loadlock chamber 508 and the transfer chamber 506 via a slit valve 842. The loadlock chamber 508 comprises a carrier support 844 adapted to support incoming and outgoing carrier plates thereon. In one embodiment, the loadlock chamber 508 may comprise multiple carrier supports that are vertically stacked. To facilitate loading and unloading of a carrier plate, the carrier support 844 may be coupled to a stem 846 vertically movable to adjust the height of the carrier support 844. The loadlock chamber 508 is coupled to a pressure control system (not shown) which pumps down and vents the loadlock chamber 508 to facilitate passing the substrate between the vacuum environment of the transfer chamber 506 and the substantially ambient (e.g., atmospheric) environment of the load station 510. In addition, the loadlock chamber 508 may also comprise features for temperature control, such as a degas module 848 to heat substrates and remove moisture, or a cooling station (not shown) for cooling substrates during transfer. Once a carrier plate loaded with substrates has been conditioned in the loadlock chamber 508, the carrier plate may be transferred into the MOCVD chamber 502 or the HVPE chamber 504 for processing, or to the batch loadlock chamber 509 where multiple carrier plates are stored in standby for processing.

During operation, a carrier plate 712 containing a batch of substrates is loaded on the conveyor tray 706 in the load station 510. The conveyor tray 706 is then moved through the slit valve 710 into the loadlock chamber 508, placing the carrier plate 712 onto the carrier support 844 inside the loadlock chamber 508, and the conveyor tray returns to the load station 510. While the carrier plate 712 is inside the loadlock chamber 508, the loadlock chamber 508 is pumped and purged with an inert gas, such as nitrogen, in order to remove any remaining oxygen, water vapor, and other types of contaminants. After the batch of substrates have been conditioned in the loadlock chamber, the robot assembly 530 may transfer the carrier plate 712 to either the MOCVD chamber 502 or, the HVPE chamber 504 to undergo deposition processes. In alternate embodiments, the carrier plate 712 may be transferred and stored in the batch loadlock chamber 509 on standby for processing in either the MOCVD chamber 502 or the HVPE chamber 504. After processing of the batch of substrates is complete, the carrier plate 712 may be transferred to the loadlock chamber 508, and then retrieved by the conveyor tray 706 and returned to the load station 510.

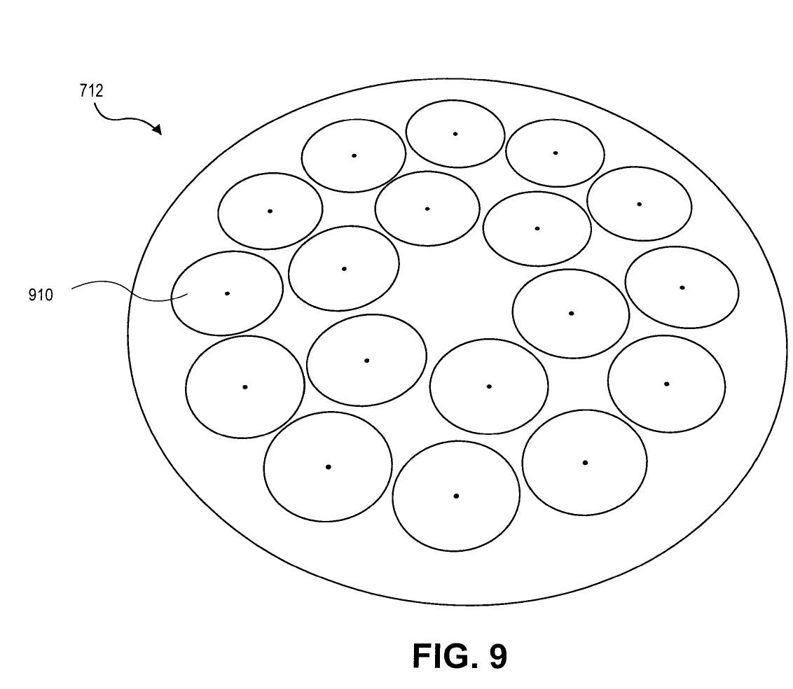

FIG. 9 is an isometric view of a carrier plate according to an embodiment of the invention. In one embodiment, the carrier plate 712 may include one or more circular recesses 910 within which individual substrates may be disposed during processing. The size of each recess 910 may be changed according to the size of the substrate to accommodate therein. In one embodiment, the carrier plate 712 may carry six or more substrates. In another embodiment, the carrier plate 712 carries eight substrates. In yet another embodiment, the carrier plate 712 carries 18 substrates. It is to be understood that more or less substrates may be carried on the carrier plate 712. Typical substrates may include sapphire, silicon carbide (SiC), silicon, or gallium nitride (GaN). It is to be understood that other types of substrates, such as glass substrates, may be processed. Substrate size may range from 50 mm-200 mm in diameter or larger. In one embodiment, each recess 910 may be sized to receive a circular substrate having a diameter between about 2 inches and about 6 inches. The diameter of the carrier plate 712 may range from 200 mm-750 mm, for example, about 300 mm. The carrier plate 712 may be formed from a variety of materials, including SiC, SiC-coated graphite, or other materials resistant to the processing environment. Substrates of other sizes may also be processed within the processing system 500 according to the processes described herein.

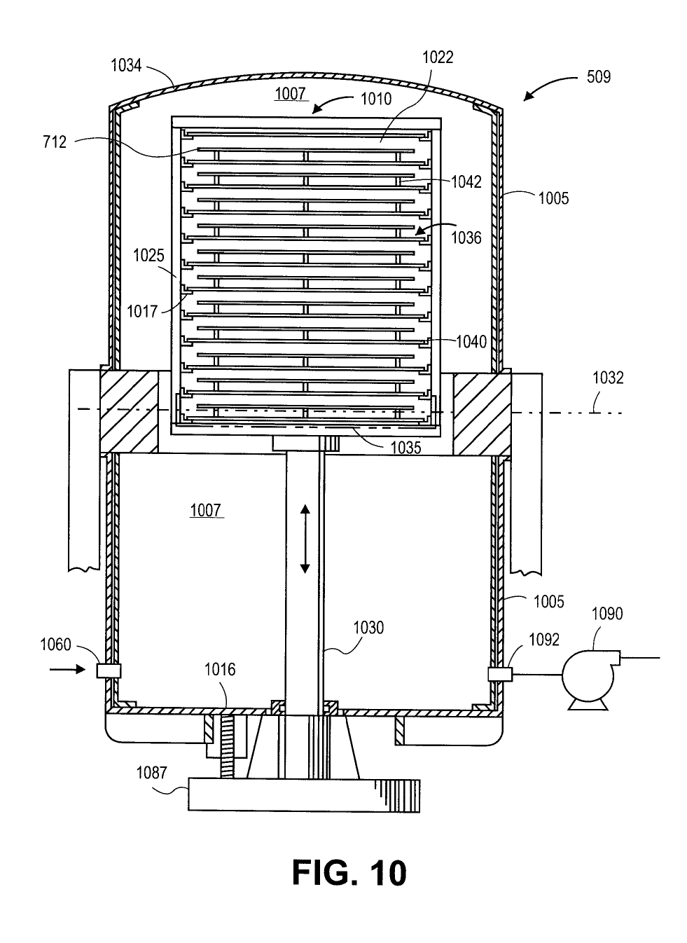

FIG. 10 is a schematic view of the batch loadlock chamber 509 according to an embodiment of the invention. The batch loadlock chamber 509 comprises a body 1005 and a lid 1034 and bottom 1016 disposed on the body 1005 and defining a cavity 1007 for storing a plurality of substrates placed on the carrier plates 712 therein. In one aspect, the body 1005 is formed of process resistant materials such as aluminum, steel, nickel, and the like, adapted to withstand process temperatures and is generally free of contaminates such as copper. The body 1005 may comprise a gas inlet 1060 extending into the cavity 1007 for connecting the batch loadlock chamber 509 to a process gas supply (not shown) for delivery of processing gases therethrough. In another aspect, a vacuum pump 1090 may be coupled to the cavity 1007 through a vacuum port 1092 to maintain a vacuum within the cavity 1007.

A storage cassette 1010 is moveably disposed within the cavity 1007 and is coupled with an upper end of a movable member 1030. The moveable member 1030 is comprised of process resistant materials such as aluminum, steel, nickel, and the like, adapted to withstand process temperatures and generally free of contaminates such as copper. The movable member 1030 enters the cavity 1007 through the bottom 1016. The movable member 1030 is slidably and sealably disposed through the bottom 1016 and is raised and lowered by the platform 1087. The platform 1087 supports a lower end of the movable member 1030 such that the movable member 1030 is vertically raised or lowered in conjunction with the raising or lowering of the platform 1087. The movable member 1030 vertically raises and lowers the storage cassette 1010 within the cavity 1007 to move the substrates carrier plates 712 across a substrate transfer plane 1032 extending through a window 1035. The substrate transfer plane 1032 is defined by the path along which substrates are moved into and out of the storage cassette 1010 by the robot assembly 530.

The storage cassette 1010 comprises a plurality of storage shelves 1036 supported by a frame 1025. Although in one aspect, FIG. 10 illustrates twelve storage shelves 1036 within storage cassette 1010, it is contemplated that any number of shelves may be used. Each storage shelf 1036 comprises a substrate support 1040 connected by brackets 1017 to the frame 1025. The brackets 1017 connect the edges of the substrate support 1040 to the frame 1025 and may be attached to both the frame 1025 and substrate support 1040 using adhesives such as pressure sensitive adhesives, ceramic bonding, glue, and the like, or fasteners such as screws, bolts, clips, and the like that are process resistant and are free of contaminates such as copper. The frame 1025 and brackets 1017 are comprised of process resistant materials such as ceramics, aluminum, steel, nickel, and the like that are process resistant and are generally free of contaminates such as copper. While the frame 1025 and brackets 1017 may be separate items, it is contemplated that the brackets 1017 may be integral to the frame 1025 to form support members for the substrate supports 1040.

The storage shelves 1036 are spaced vertically apart and parallel within the storage cassette 1010 to define a plurality of storage spaces 1022. Each substrate storage space 1022 is adapted to store at least one carrier plate 712 therein supported on a plurality of support pins 1042. The storage shelves 1036 above and below each carrier plate 712 establish the upper and lower boundary of the storage space 1022.

In another embodiment, substrate support 1040 is not present and the carrier plates 712 rest on brackets 1017.

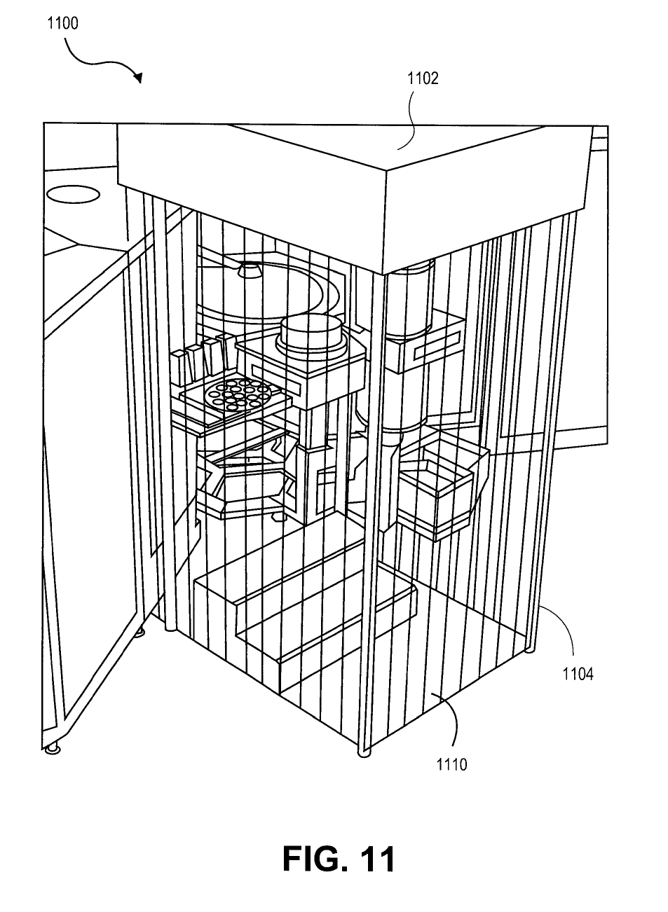

FIG. 11 is an isometric view of a work platform 1100 according to one embodiment of the invention. In one embodiment, the processing system 500 further comprises a work platform 1100 enclosing the load station 510. The work platform 1100 provides a particle free environment during loading and unloading of substrates into the load station 510. The work platform 1100 comprises a top portion 1102 supported by four posts 1104. A curtain 1110 separates the environment inside the work platform 1100 from the surrounding environment. In one embodiment, the curtain 1110 comprises a vinyl material. In one embodiment the work platform comprises an air filter, such as a High Efficiency Particulate Air Filter (“HEPA”) filter for filtering airborne particles from the ambient inside the work platform. In one embodiment, air pressure within the enclosed work platform 1100 is maintained at a slightly higher pressure than the atmosphere outside of the work platform 1100 thus causing air to flow out of the work platform 1100 rather than into the work platform 1100.

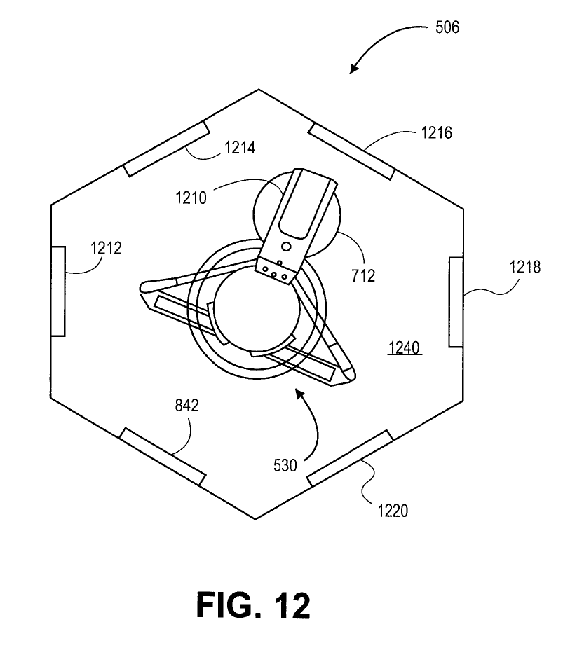

FIG. 12 is a plan view of a robot assembly 530 shown in the context of the transfer chamber 506. The internal region (e.g., transfer region 1240) of the transfer chamber 506 is typically maintained at a vacuum condition and provides an intermediate region in which to shuttle substrates from one chamber to another and/or to the loadlock chamber 508 and other chambers in communication with the cluster tool. The vacuum condition is typically achieved by use of one or more vacuum pumps (not shown), such as a conventional rough pump, Roots Blower, conventional turbo-pump, conventional cryo-pump, or combination thereof. Alternately, the internal region of the transfer chamber 506 may be an inert environment that is maintained at or near atmospheric pressure by continually delivering an inert gas to the internal region. Three such platforms are the Centura, the Endura and the Producer system all available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

The robot assembly 530 is centrally located within the transfer chamber 506 such that substrates can be transferred into and out of adjacent processing chambers, the loadlock chamber 508, and the batch loadlock chamber 509, and other chambers through slit valves 842, 1212, 1214, 1216, 1218, and 1220 respectively. The valves enable communication between the processing chambers, the loadlock chamber 508, the batch loadlock chamber 509, and the transfer chamber 506 while also providing vacuum isolation of the environments within each of the chambers to enable a staged vacuum within the system. The robot assembly 530 may comprise a frog-leg mechanism. In certain embodiments, the robot assembly 530 may comprise any variety of known mechanical mechanisms for effecting linear extension into and out of the various process chambers. A blade 1210 is coupled with the robot assembly 530. The blade 1210 is configured to transfer the carrier plate 712 through the processing systems. In one embodiment, the processing system 500 comprises an automatic center finder (not shown). The automatic center finder allows for the precise location of the carrier plate 712 on the robot assembly 530 to be determined and provided to a controller. Knowing the exact center of the carrier plate 712 allows the computer to adjust for the variable position of each carrier plate 712 on the blade and precisely position each carrier plate 712 in the processing chambers.

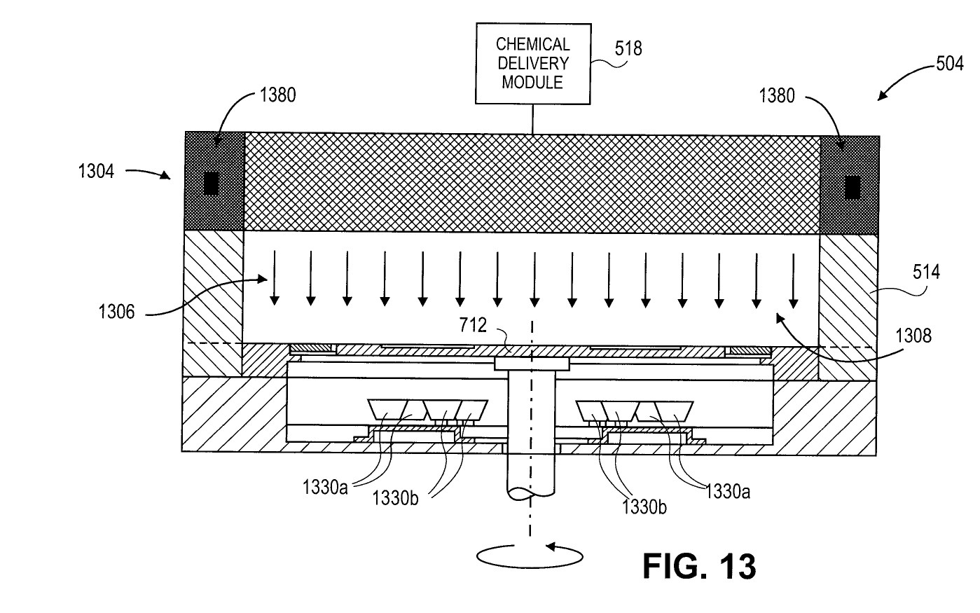

FIG. 13 is a schematic cross-sectional view of a HVPE chamber 504 according to an embodiment of the invention. The HVPE chamber 504 includes the chamber body 514 that encloses a processing volume 1308. A showerhead assembly 1304 is disposed at one end of the processing volume 1308, and the carrier plate 712 is disposed at the other end of the processing volume 1308. The showerhead assembly, as described above, may allow for more uniform deposition across a greater number of substrates or larger substrates than in traditional HVPE chambers, thereby reducing production costs. The showerhead may be coupled with a chemical delivery module 518. The carrier plate 712 may rotate about its central axis during processing. In one embodiment, the carrier plate 712 may be rotated at about 2 RPM to about 100 RPM. In another embodiment, the carrier plate 712 may be rotated at about 30 RPM. Rotating the carrier plate 712 aids in providing uniform exposure of the processing gases to each substrate.

A plurality of lamps 1330a, 1330b may be disposed below the carrier plate 712. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 1330b may include eight lamps, and the outer array of lamps 1330a may include twelve lamps. In one embodiment of the invention, the lamps 1330a, 1330b are each individually powered. In another embodiment, arrays of lamps 1330a, 1330b may be positioned above or within showerhead assembly 1304. It is understood that other arrangements and other numbers of lamps are possible. The arrays of lamps 1330a, 1330b may be selectively powered to heat the inner and outer areas of the carrier plate 712. In one embodiment, the lamps 1330a, 1330b are collectively powered as inner and outer arrays in which the top and bottom arrays are either collectively powered or separately powered. In yet another embodiment, separate lamps or heating elements may be positioned over and/or under the source boat 1380. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639, published Jan. 26, 2006, entitled PROCESSING MULTILAYER SEMICONDUCTORS WITH MULTIPLE HEAT SOURCES, which is incorporated by reference in its entirety.

In yet another embodiment, the source boat 1380 is remotely located with respect to the chamber body 514, as described in U.S. Provisional Patent Application Ser. No. 60/978,040, filed Oct. 5, 2007, titled METHOD FOR DEPOSITING GROUP III/V COMPOUNDS, which is incorporated by reference in its entirety.

One or more lamps 1330a, 1330b may be powered to heat the substrates as well as the source boat 1380. The lamps may heat the substrate to a temperature of about 900° C. to about 1200° C. In another embodiment, the lamps 1330a, 1330b maintain a metal source within the source boat 1380 at a temperature of about 350° C. to about 900° C. A thermocouple may be used to measure the metal source temperature during processing. The temperature measured by the thermocouple may be fed back to a controller that adjusts the heat provided from the heating lamps 1330a, 1330b so that the temperature of the metal source may be controlled or adjusted as necessary.

Precursor gases 1306 flow from the showerhead assembly 1304 towards the substrate surface. Reaction of the precursor gases 1306 at or near the substrate surface may deposit various metal nitride layers upon the substrate, including GaN, AlN, and InN. Multiple metals may also be utilized for the deposition of “combination films” such as AlGaN and/or InGaN. The processing volume 1308 may be maintained at a pressure of about 760 torr down to about 100 torr. In one embodiment, the processing volume 1308 is maintained at a pressure of about 450 torr to about 760 torr. Exemplary embodiments of the showerhead assembly 1304 and other aspects of the HVPE chamber are described in U.S. patent application Ser. No. 11/767,520, filed Jun. 24, 2007, entitled HVPE TUBE SHOWERHEAD DESIGN, which is herein incorporated by reference in its entirety. Exemplary embodiments of the HVPE chamber 504 are described in U.S. Patent Application Ser. No. 61/172,630, filed Apr. 24, 2009, entitled HVPE CHAMBER HARDWARE, which is herein incorporated by reference in its entirety. Alternatively, Cl₂ gas may be fed into the processing volume under conditions set forth above to form a nanocrystalline diamond-structure carbon coating on a silicon carbide substrate or silicon carbide layer on a substrate contained within volume 1308 or on silicon carbide chamber components or parts within volume 1308.

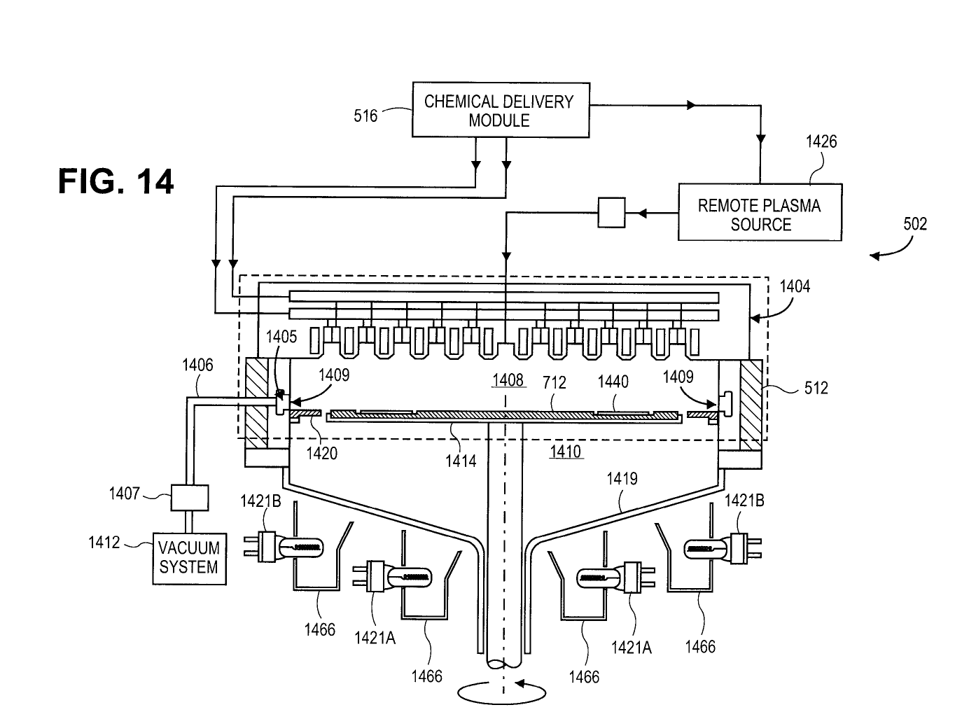

FIG. 14 is a schematic cross-sectional view of an MOCVD chamber according to an embodiment of the invention. The MOCVD chamber 502 comprises a chamber body 512, a chemical delivery module 516, a remote plasma source 1426, a substrate support 1414, and a vacuum system 1412. The chamber 502 includes a chamber body 512 that encloses a processing volume 1408. A showerhead assembly 1404 is disposed at one end of the processing volume 1408, and a carrier plate 712 is disposed at the other end of the processing volume 1408. The carrier plate 712 may be disposed on the substrate support 1414. In an embodiment of the present invention, Cl₂ gas may be fed into processing volume 1408 under conditions set forth above to form a nanocrystalline diamond structure carbon coating on a silicon carbide substrate or silicon carbide layer on a substrate contained in processing volume 1408 or onto silicon carbide chamber components or parts within volume 1408. Exemplary showerheads that may be adapted to practice the present invention are described in U.S. patent application Ser. No. 11/873,132, filed Oct. 16, 2007, entitled MULTI-GAS STRAIGHT CHANNEL SHOWERHEAD, U.S. patent application Ser. No. 11/873,141, filed Oct. 16, 2007, entitled MULTI-GAS SPIRAL CHANNEL SHOWERHEAD, and 11/873,170, filed Oct. 16, 2007, entitled MULTI-GAS CONCENTRIC INJECTION SHOWERHEAD, all of which are incorporated by reference in their entireties.

A lower dome 1419 is disposed at one end of a lower volume 1410, and the carrier plate 712 is disposed at the other end of the lower volume 1410. The carrier plate 712 is shown in process position, but may be moved to a lower position where, for example, the substrates 1440 may be loaded or unloaded. An exhaust ring 1420 may be disposed around the periphery of the carrier plate 712 to help prevent deposition from occurring in the lower volume 1410 and also help direct exhaust gases from the chamber 502 to exhaust ports 1409. The lower dome 1419 may be made of transparent material, such as high-purity quartz, to allow light to pass through for radiant heating of the substrates 1440. The radiant heating may be provided by a plurality of inner lamps 1421A and outer lamps 1421B disposed below the lower dome 1419 and reflectors 1466 may be used to help control the chamber 502 exposure to the radiant energy provided by inner and outer lamps 1421A, 1421B. Additional rings of lamps may also be used for finer temperature control of the substrates 1440.

A purge gas (e.g., nitrogen) may be delivered into the chamber 502 from the showerhead assembly 1404 and/or from inlet ports or tubes (not shown) disposed below the carrier plate 712 and near the bottom of the chamber body 512. The purge gas enters the lower volume 1410 of the chamber 502 and flows upwards past the carrier plate 712 and exhaust ring 1420 and into multiple exhaust ports 1409 which are disposed around an annular exhaust channel 1405. An exhaust conduit 1406 connects the annular exhaust channel 1405 to a vacuum system 1412 which includes a vacuum pump (not shown). The chamber 502 pressure may be controlled using a valve system 1407 which controls the rate at which the exhaust gases are drawn from the annular exhaust channel 1405. Other aspects of the MOCVD chamber are described in U.S. patent application Ser. No. 12/023,520, filed Jan. 31, 2008, (attorney docket no. 011977) entitled CVD APPARATUS, which is herein incorporated by reference in its entirety.

Various metrology devices, such as, for example, reflectance monitors, thermocouples, or other temperature devices may also be coupled with the chamber 502. The metrology devices may be used to measure various film properties, such as thickness, roughness, composition, temperature or other properties. These measurements may be used in an automated real-time feedback control loop to control process conditions such as deposition rate and the corresponding thickness. Other aspects of chamber metrology are described in U.S. Patent Application Ser. No. 61/025,252, filed Jan. 31, 2008, (attorney docket no. 011007) entitled CLOSED LOOP MOCVD DEPOSITION CONTROL, which is herein incorporated by reference in its entirety.

The chemical delivery modules 516, 518 supply chemicals to the MOCVD chamber 502 and HVPE chamber 504 respectively. Reactive and carrier gases are supplied from the chemical delivery system through supply lines into a gas mixing box where they are mixed together and delivered to respective showerheads 1404 and 1304. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

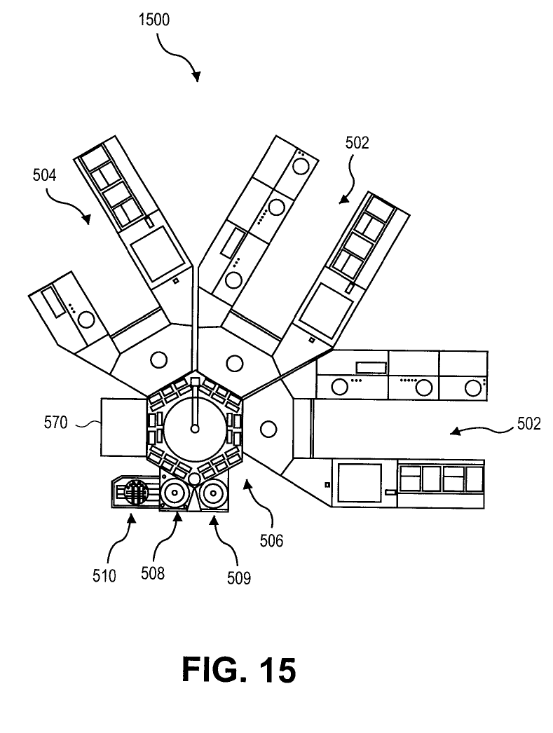

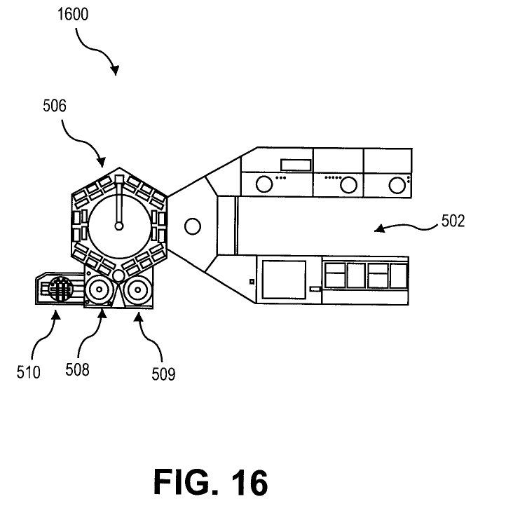

While the foregoing embodiments have been described in connection to a processing system that comprises one MOCVD chamber and one HVPE chamber, alternate embodiments may integrate one or more MOCVD and HVPE chambers in the processing system, as shown in FIGS. 15 and 16. FIG. 15 illustrates an embodiment of a processing system 1500 that comprises two MOCVD chambers 502 and one HVPE chamber 504 coupled to the transfer chamber 506. In the processing system 1500, the robot blade is operable to respectively transfer a carrier plate into each of the MOCVD chambers 502 and HVPE chamber 504. Multiple batches of substrates loaded on separate carrier plates thus can be processed in parallel in each of the MOCVD chambers 502 and HVPE chamber 504.

FIG. 16 illustrates a simpler embodiment of a processing system 1600 that comprises a single MOCVD chamber 502. In the processing system 1600, the robot blade transfers a carrier plate loaded with substrates into the single MOCVD chamber 502 to undergo deposition. After all the deposition steps have been completed, the carrier plate is transferred from the MOCVD chamber 502 back to the loadlock chamber 508, and then released toward the load station 510.

A system controller 560 controls activities and operating parameters of the processing system 500. The system controller 560 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, entitled EPITAXIAL GROWTH OF COMPOUND NITRIDE STRUCTURES, which is hereby incorporated by reference in its entirety.

The system controller 560 and related control software prioritize tasks and substrate movements based on inputs from the user and various sensors distributed throughout the processing system 500. The system controller 560 and related control software allow for automation of the scheduling/handling functions of the processing system 500 to provide the most efficient use of resources without the need for human intervention. In one aspect, the system controller 560 and related control software adjust the substrate transfer sequence through the processing system 500 based on a calculated optimized throughput or to work around processing chambers that have become inoperable. In another aspect, the scheduling/handling functions pertain to the sequence of processes required for the fabrication of compound nitride structures on substrates, especially for processes that occur in one or more processing chambers. In yet another aspect, the scheduling/handling functions pertain to efficient and automated processing of multiple batches of substrates, whereby a batch of substrates is contained on a carrier. In yet another aspect, the scheduling/handling functions pertain to periodic in-situ cleaning of processing chambers or other maintenance related processes. In yet another aspect, the scheduling/handling functions pertain to temporary storage of substrates in the batch loadlock chamber. In yet another aspect the scheduling/handling functions pertain to transfer of substrates to or from the load station based on operator inputs.

The following example is provided to illustrate how the general process described in connection with processing system 500 may be used for the fabrication of compound nitride structures. The example refers to a LED structure, with its fabrication being performed using a processing system 500 having at least two processing chambers, such as MOCVD chamber 502 and HVPE chamber 504. The cleaning and deposition of the initial GaN layers is performed in the HVPE chamber 504, with growth of the remaining InGaN, AlGaN, and GaN contact layers being performed in the MOCVD system 502.

The process begins with a carrier plate containing multiple substrates being transferred into the HVPE chamber 504. The HVPE chamber 504 is configured to provide rapid deposition of GaN. A pretreatment process and/or buffer layer is grown over the substrate in the HVPE chamber 504 using HVPE precursor gases. This is followed by growth of a thick n-GaN layer, which in this example is performed using HVPE precursor gases. In another embodiment the pretreatment process and/or buffer layer is grown in the MOCVD chamber and the thick n-GaN layer is grown in the HVPE chamber.

After deposition of the n-GaN layer, the substrate is transferred out of the HVPE chamber 504 and into the MOCVD chamber 502, with the transfer taking place in a high-purity N₂ atmosphere via the transfer chamber 506. The MOCVD chamber 502 is adapted to provide highly uniform deposition, perhaps at the expense of overall deposition rate. In the MOCVD chamber 502, the InGaN multi-quantum-well active layer is grown after deposition of a transition GaN layer. This is followed by deposition of the p-AlGaN layer and p-GaN layer. In another embodiment the p-GaN layer is grown in the HVPE chamber.

The completed structure is then transferred out of the MOCVD chamber 502 so that the MOCVD chamber 502 is ready to receive an additional carrier plate containing partially processed substrates from the HVPE chamber 504 or from a different processing chamber. The completed structure may either be transferred to the batch loadlock chamber 509 for storage or may exit the processing system 500 via the loadlock chamber 508 and the load station 510.

Before receiving additional substrates the HVPE chamber and/or MOCVD chamber may be cleaned via an in-situ clean process. The cleaning process may comprise etchant gases which thermally etch deposition from chamber walls and surfaces. In another embodiment, the cleaning process comprises a plasma generated by a remote plasma generator. Exemplary cleaning processes are described in U.S. patent application Ser. No. 11/404,516, filed on Apr. 14, 2006, and U.S. patent application Ser. No. 11/767,520, filed on Jun. 24, 2007, titled HVPE SHOWERHEAD DESIGN, both of which are incorporated by reference in their entireties.

An improved system and method for fabricating compound nitride semiconductor devices has been provided. In conventional manufacturing of compound nitride semiconductor structures, multiple epitaxial deposition steps are performed in a single process reactor, with the substrate not leaving the process reactor until all of the steps have been completed resulting in a long processing time, usually on the order of 4-6 hours. Conventional systems also require that the reactor be manually opened in order to remove and insert additional substrates. After opening the reactor, in many cases, an additional 4 hours of pumping, purging, cleaning, opening, and loading must be performed resulting in a total run time of about 8-10 hours per substrate. The conventional single reactor approach also prevents optimization of the reactor for individual process steps.

The improved system provides for simultaneously processing substrates using a multi-chamber processing system that has an increased system throughput, increased system reliability, and increased substrate to substrate uniformity. The multi-chamber processing system expands the available process window for different compound structures by performing epitaxial growth of different compounds in different processing having structures adapted to enhance those specific procedures. Since the transfer of substrates is automated and performed in a controlled environment, this eliminates the need for opening the reactor and performing a long pumping, purging, cleaning, opening, and loading process.

Thus, a method of forming a nanocrystalline diamond-structured carbon layer on a silicon carbide layer has been described.

1. A method of forming a carbon layer on a silicon carbide layer comprising:
providing a silicon carbide layer in a reaction chamber; and
forming a carbon layer on the silicon carbide layer by introducing a chlorine containing gas into the reaction chamber and exposing the silicon carbide layer to the chlorine containing gas for an exposure time period to transform a portion of the silicon carbide layer to the carbon layer, wherein the carbon layer.

2. The method of claim 1, wherein the carbon layer is formed to a kinetically limited thickness.

3. The method of claim 1, wherein the carbon layer is a nanocrystalline diamond-structured carbon layer.

4. The method of claim 1, wherein the silicon carbide layer is selected from the group consisting of: a single crystalline carbide layer, a hot pressed silicon carbide layer, and a polycrystalline silicon carbide layer.

5. The method of claim 1, further comprising heating the silicon carbide layer to a temperature between 600° C. and 1000° C.

6. The method of claim 1, further comprising reducing the reaction chamber pressure to between 5 torr and 760 torr.

7. The method of claim 1, wherein the exposure time period is between one minute and 12.0 hours.

8. The method of claim 1, wherein the chlorine containing gas is selected from the group consisting of Cl₂ and HCl.

9. The method of claim 1, further comprising flowing the chlorine containing gas into the reaction chamber at a flow rate between 1.0 and 7.0 standard liters per minute.

10. The method of claim 1, further comprising flowing an inert gas into the reaction chamber at a flow rate between 1.0 and 7.0 standard liters per minute.

11. The method of claim 10, wherein the inert gas is selected from the group consisting of N₂, Ar and He.
